(19) United States
(12) Patent Application Publication
(10) Pub. No.: US 2024/0304657 A1
(43) Pub. Date: Sep. 12, 2024

(54) SEMICONDUCTOR DEVICE AND METHOD FOR FABRICATING THE SAME

(71) Applicant: UNITED MICROELECTRONICS CORP., Hsin-Chu City (TW)

(72) Inventors: Yi-Chun Teng, Taichung City (TW); Ming-Che Tsai, Tainan City (TW); Ping-Chia Shih, Tainan City (TW); Yi-Chang Huang, Tainan City (TW); Wen-Lin Wang, Kaohsiung City (TW); Yu-Fan Hu, Tainan City (TW); Ssu-Yin Liu, Kaohsiung City (TW); Yu-Nong Chen, Miaoli County (TW); Pei-Tsen Shiu, Tainan City (TW); Cheng-Tzung Tsai, Taipei City (TW)

(73) Assignee: UNITED MICROELECTRONICS CORP., Hsin-Chu City (TW)

(21) Appl. No.: 18/128,218

(22) Filed: Mar. 29, 2023

(30) Foreign Application Priority Data
Mar. 6, 2023 (CN) 202310204740.6

(51) Int. Cl. H01L 27/06

(52) U.S. Cl. CPC H01L 28/24; H01L 27/0629

(57) ABSTRACT

A semiconductor device includes a substrate, a first gate, a plurality of second gates and a resistor. The substrate is defined with an active region and a resistor region. The first gate is disposed in the active region. The first gate has a first length extending along a first direction and a second length extending along a second direction. The plurality of second gates are disposed in the resistor region. Each of the second gates has a third length extending along the first direction and a fourth length extending along the second direction. The first length is equal to the third length, and the second length is equal to the fourth length. The resistor is disposed on the plurality of second gates.

### BACKGROUND OF THE INVENTION

### 1. Field of the Invention

The present disclosure relates to the field of semiconductor devices, and more particularly, to a semiconductor device having a resistor and a method for fabricating the same.

### 2. Description of the Prior Art

In the field of semiconductor, polysilicon is widely used as a gate material for metal oxide semiconductor field effect transistors (MOSFET) due to its excellent thermal stability. However, polysilicon has a higher resistor value. Moreover, when the high-k materials are used as the gate insulating layer, polysilicon tends to react with the high-k materials, which results in defects in the gate/gate insulating layer. According to the required performance of the semiconductor device, polysilicon is gradually replaced by the metal materials, and the metal materials become the mainstream of the gate materials.

Therefore, it is an important issue for the relevant industry to improve the structure and fabricating method of the semiconductor device, such that the semiconductor device can combine the metal gates with other passive components such as resistors, and the semiconductor device can meet the requirements.

### SUMMARY OF THE INVENTION

According to one aspect of the present disclosure, a semiconductor device includes a substrate, a first gate, a plurality of second gates and a resistor. The substrate is defined with an active region and a resistor region. The first gate is disposed in the active region. The first gate has a first length extending along a first direction and a second length extending along a second direction. The plurality of second gates are disposed in the resistor region. Each of the second gates has a third length extending along the first direction and a fourth length extending along the second direction. The first length is equal to the third length, and the second length is equal to the fourth length. The resistor is disposed on the plurality of second gates.

According to another aspect of the present disclosure, a method for fabricating a semiconductor device includes steps as follows. A substrate is provided, wherein the substrate is defined with an active region and a resistor region. A first gate is formed in the active region, wherein the first gate has a first length extending along a first direction and a second length extending along a second direction. A plurality of second gates are formed in the resistor region, wherein each of the second gates has a third length extending along the first direction and a fourth length extending along the second direction, the first length is equal to the third length, and the second length is equal to the fourth length. A resistor is formed on the plurality of second gates.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic cross-sectional view of a semiconductor device according to one embodiment of the present disclosure.

FIG. 2 is a schematic top view of the semiconductor device in FIG. 1.

FIG. 3 is a schematic top view of a semiconductor device according to another embodiment of the present disclosure.

FIG. 4 is a schematic cross-sectional view of a semiconductor device according to further another embodiment of the present disclosure.

FIG. 5 is a schematic cross-sectional view of a semiconductor device according to yet another embodiment of the present disclosure.

FIG. 6 is a schematic cross-sectional view of a semiconductor device according to yet another embodiment of the present disclosure.

FIG. 7 is a schematic cross-sectional view of a semiconductor device according to yet another embodiment of the present disclosure.

FIG. 8 is a flow diagram showing a method for fabricating a semiconductor device according to another embodiment of the present disclosure.

FIG. 9 and FIG. 10 are schematic diagrams showing steps of the method for fabricating the semiconductor device in FIG. 8.

### DETAILED DESCRIPTION

In the following detailed description of the embodiments, reference is made to the accompanying drawings which form a part thereof, and in which is shown by way of illustration specific embodiments in which the disclosure may be practiced. In this regard, directional terminology, such as up, down, left, right, front, back, bottom, top, etc., is used with reference to the orientation of the Figure (s) being described. The components of the present disclosure can be positioned in a number of different orientations. As such, the directional terminology is used for purposes of illustration and is in no way limiting. In addition, identical numeral references or similar numeral references are used for identical components or similar components in the following embodiments.

Hereinafter, for the description of “the first feature is formed on or above the second feature”, it may refer that “the first feature is in contact with the second feature directly”, or it may refer that “there is another feature between the first feature and the second feature”, such that the first feature is not in contact with the second feature directly.

It is understood that, although the terms first, second, etc. may be used herein to describe various components, regions, layers and/or sections, these components, regions, layers and/or sections should not be limited by these terms. These terms may be only used to distinguish one component, region, layer and/or section from another component, region, layer and/or section. Terms such as “first,” “second,” and other numerical terms when used herein do not imply a sequence or order unless clearly indicated by the context. Thus, a first component, region, layer and/or section discussed below could be termed a second component, region, layer and/or section without departing from the teachings of the embodiments. The terms used in the claims may not be identical with the terms used in the specification, but may be used according to the order of the components claimed in the claims.

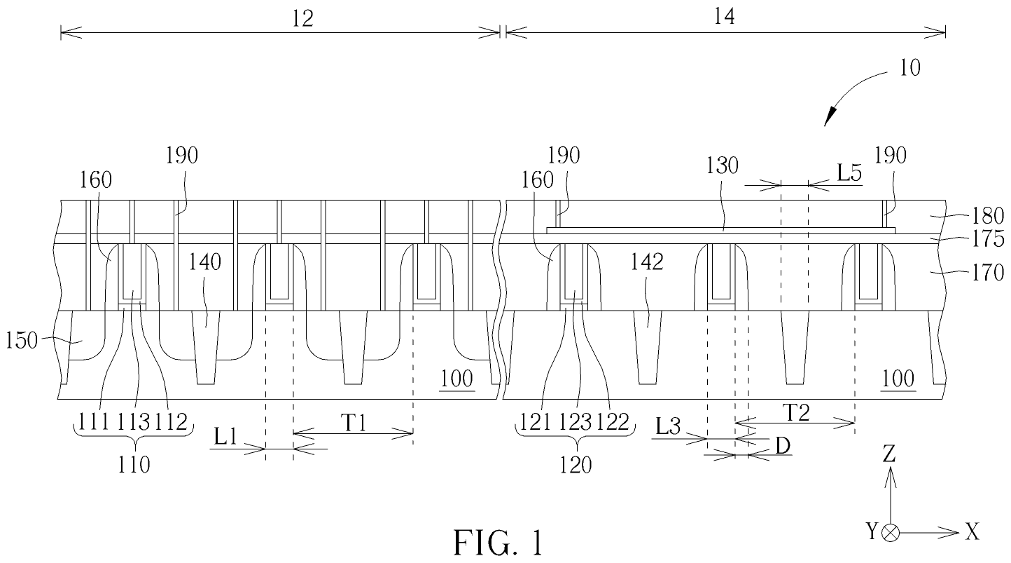

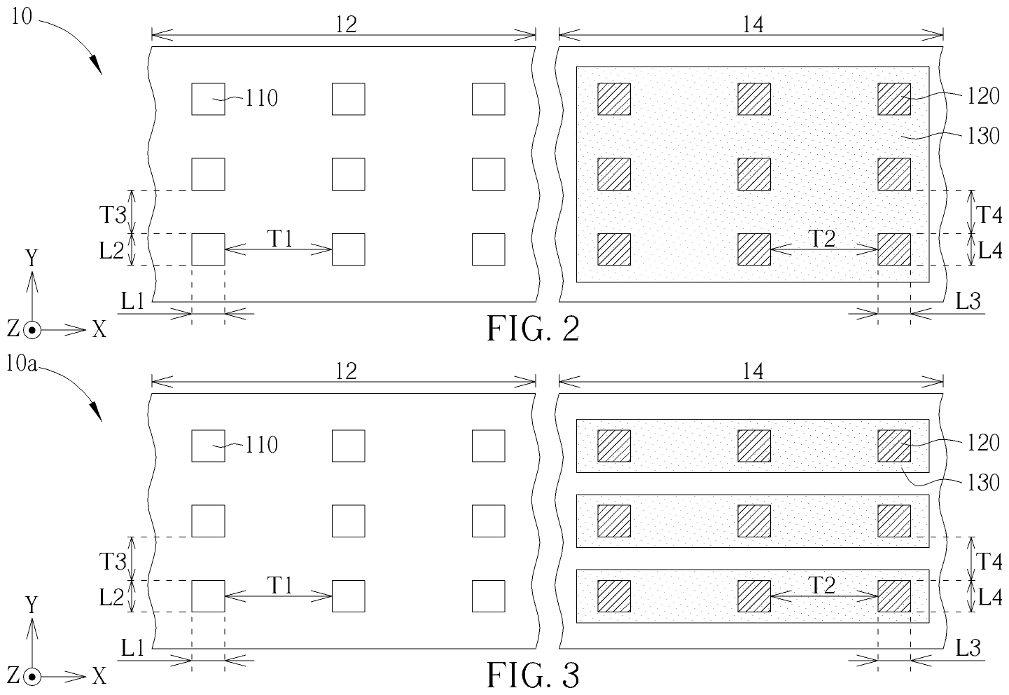

Please refer to FIG. 1 and FIG. 2. FIG. 1 is a schematic cross-sectional view of a semiconductor device 10 according to one embodiment of the present disclosure. FIG. 2 is a schematic top view of the semiconductor device 10 in FIG. 1. In FIG. 2, only first gates 110, second gates 120 and a resistor 130 are shown for clearly showing the relationship therebetween, and other components in FIG. 1 are omitted.

The semiconductor device 10 includes a substrate 100, a plurality of first gates 110, a plurality of second gates 120 and the resistor 130. The substrate 100 is defined with an active region 12 and a resistor region 14. The first gates are disposed in the active region 12, the second gates 120 are disposed in the resistor region 14, and the resistor 130 is disposed on the second gates 120. Thereby, the second gates 120 can be configured to support the resistor 130, so as to prevent the resistor 130 from dishing due to lack of support during the planarization process such as chemical mechanical polishing (CMP).

Each of the first gates 110 has a first length L1 extending along a first direction (such as the direction X) and a second length L2 extending along a second direction (such as the direction Y). Each of the second gates 120 has a third length L3 extending along the first direction and a fourth length L4 extending along the second direction. The first length L1 is equal to the third length L3, and the second length L2 is equal to the fourth length L4. In other words, the shape of the projection of the second gate 120 on the XY plane is identical to the shape of the projection of the first gate 110 on the XY plane. In the case that the shape of the projection of the second gate 120 is different from the shape of the projection of the first gate 110 on the XY plane, such as the first length L1 being greater than or less than the third length L3 and/or the second length L2 being greater than or less than the fourth length L4, when the replacement metal gate (RMG) process is performed, the parameters for removing the gate material such as polysilicon in the first gate 110 and the second gate 120 having different lengths in the first direction/second direction are different. When the parameter is determined based on the gate with the longer length, the gate material of the gate with the shorter length may be residual. When the parameter is determined based on the gate with the shorter length, the height of the gate with the longer length may be lower than that of the gate with the shorter length, so that the metal material subsequently filled in the gate may form metal bridges between different gates caused by the CMP.

In the embodiment, the first direction is perpendicular to the second direction, but not limited thereto. In other embodiments, the first direction may not be perpendicular to the second direction. For example, the angle between the first direction and the second direction may be greater than 0 degree and less than or equal to 90 degrees. That is, in the present disclosure, the first direction is different from the second direction.

Specifically, the substrate 100 may be a semiconductor substrate, such as a silicon substrate, an epitaxial silicon substrate, a silicon carbide substrate or a silicon on insulator (SOI) substrate.

The first gate 110 and the second gate 120 may be metal gates. Each of the first gates 110 may include a gate dielectric layer 111, a high-K dielectric layer 112 and a metal layer 113. Each of the second gates 120 may include a gate dielectric layer 121, a high-K dielectric layer 122 and a metal layer 123. The gate dielectric layers 111 and 121 are disposed on the substrate 100. The materials of the gate dielectric layers 111 and 121, for example, may independently include silicon dioxide, silicon nitride or high dielectric constant (high-k) materials. The high-K dielectric layer 112 may be disposed between the gate dielectric layer 111 and the metal layer 113 in a U-shape. The high-K dielectric layer 122 may be disposed between the gate dielectric layer 121 and the metal layer 123 in a U-shape. The materials of the high-K dielectric layers 112 and 122, for example, may independently include a dielectric material with a dielectric constant greater than 4, which may be a group selected from hafnium oxide (HfO₂), hafnium silicon oxide (HfSiO₄), hafnium silicon oxynitride (HfSiON), aluminum oxide (Al₂O₃), lanthanum oxide (La₂O₃), tantalum oxide (Ta₂O₅), yttrium oxide (Y₂O₃), zirconium oxide (ZrO₂), strontium titanate oxide (SrTiO₃), zirconium silicon oxide (ZrSiO₄), hafnium zirconium oxide (HfZrO₄), strontium bismuth tantalate (SrBi₂Ta₂O₉, SBT), lead zirconate titanate (PbZrₓTi₁₋ₓO₃, PZT), barium strontium titanate (BaₓSr₁₋ₓTiO₃, BST), or a combination thereof. The materials of the metal layers 113 and 123, for example, may independently include low-resistance metal materials, which may be exemplarily selected from copper (Cu), aluminum (Al), tungsten (W), titanium aluminum alloy (TiAl), cobalt tungsten phosphide (CoWP), or a combination thereof. In addition, corresponding layers, such as barrier layers and work function metal layers, may be disposed between the gate dielectric layer 111 and the metal layer 113 or the gate dielectric layer 121 and the metal layer 123 depending on the first gate 110 being applied to an N-type metal oxide semiconductor (NMOS) or a P-type metal oxide semiconductor (PMOS).

The resistor 130 may be a single-layer or a multi-layer structure. The resistor 130 may include doped polysilicon, metal nitrides, metal oxides, or a combination thereof. The metal nitrides may be, but are not limited to, titanium nitride or tantalum nitride. The metal oxides may be, but are not limited to, materials, such as nickel oxide, titanium dioxide, zinc oxide, zirconium oxide, hafnium oxide and tantalum oxide.

The semiconductor device 10 may further include source/drain regions 150, first insulating structures 140, spacers 160, a first dielectric layer 170, a second dielectric layer 175, a third dielectric layer 180 and contact plugs 190.

The source/drain regions 150 may be formed in the substrate 100 and located on both sides of the first gate 110. The dopant of the source/drain regions 150 may be selected depending on the first gate 110 being applied to the NMOS or the PMOS. For example, when the first gate 110 is applied to the NMOS, the source/drain regions 150 may be doped with N-type impurities, such as arsenic, and phosphorus. When the first gate 110 is applied to the PMOS, the source/drain regions 150 may be doped with P-type impurities, such as boron and indium.

The first insulating structure 140 is disposed in the substrate 100 in the active region 12 and between two first gates 110. The first insulating structure 140 is configured to provide electrical isolation function. The first insulating structure 140 may be, for example, a shallow trench isolation (STI). The material of the first insulating structure 140 may include dielectric materials, such as silicon dioxide.

The spacers 160 surround the outer walls of the first gates 110 and the second gates 120. The spacer 160 may be a single-layer structure or a multi-layer structure. The material of the spacer 160 may include oxides and/or nitrides, such as silicon dioxide, silicon nitride, silicon oxynitride or silicon carbonitride.

The first dielectric layer 170 is disposed on the substrate 100 and the high-K dielectric layer 112 and the metal layer 113 of the first gate 110 and the high-K dielectric layer 122 and the metal layer 123 of the second gate 120 are exposed from the first dielectric layer 170. The top surface of the first dielectric layer 170 is aligned with the top surfaces of the first gates 110 and the second gates 120. The second dielectric layer 175 is disposed on the first dielectric layer 170 and directly contacts the first dielectric layer 170. The resistor 130 is disposed on the second dielectric layer 175 and directly contacts the second dielectric layer 175. The third dielectric layer 180 is disposed on the second dielectric layer 175 and covers and directly contacts the resistor 130. The materials of the first dielectric layer 170, the second dielectric layer 175 and the third dielectric layer 180 may independently include silicon dioxide, tetraethoxysilane (TEOS), etc.

A plurality of contact plugs 190 are disposed in the first dielectric layer 170 and/or the second dielectric layer 175 and/or the third dielectric layer 180. Each of the contact plugs 190 is connected to one of the source/drain regions 150, the first gates 110 and the resistor 130. The contact plugs 190 are configured to electrically connect the source/drain regions 150, the first gates 110 and the resistor 130 with other components. The contact plug 190 may include a multi-layer structure (not shown), for example, may include a barrier layer (not shown) and a metal layer (not shown). The barrier layer may include titanium nitride, tantalum nitride, tungsten nitride, or a combination thereof. The metal layer may include aluminum, titanium, tantalum, tungsten, niobium, molybdenum, copper, or a combination thereof. The top surface of the contact plug 190 is aligned with the top surface of the third dielectric layer 180.

In the embodiment, the semiconductor device 10 may further include at least one second insulating structure 142 disposed in the substrate 100 in the resistor region 14 and located between two second gates 120. Thereby, the insulation performance of the resistor 130 and other components may be improved, so as to improve the overall performance of the semiconductor device 10. For example, the contact plug 190 above the resistor 130 may be prevented from contacting the substrate 100 in the resistor region 14 due to misalignment. The second insulating structure 142 may be, for example, STI. The material of the second insulating structure 142 may include dielectric materials, such as silicon dioxide. The second insulating structure 142 has a fifth length L5 in the first direction (such as the direction X). The spacer 160 has a thickness D in the first direction. The second gate 120 has a third length L3 in the first direction. A total length of the second gate 120 and the spacer 160 located at two sides thereof in the first direction may be greater than or equal to the fifth length L5 of the second insulating structure 142 (that is, the following relationship may be satisfied: L3+2D≥L5). Alternatively, the third length L3 of the second gate 120 may be greater than or equal to the fifth length L5 of the second insulating structure 142 (that is, the following relationship may be satisfied: L3≥L5). Thereby, the second insulating structure 142 has a smaller size than the second gate 120 or the second gate 120 and the spacer 160 on both sides thereof, so that the probability of dishing occurred on the top surface of the second insulating structure 142 may be reduced. In the embodiment, the fifth length L5 of the second insulating structure 142 in the first direction gradually changes along the height direction (such as the direction Z) of the semiconductor device 10. The fifth length L5 may be the maximum length of the second insulating structure 142 in the first direction. In addition, compared to the active region 12, the substrate 100 in the resistor region 14 is not disposed with the source/drain regions 150.

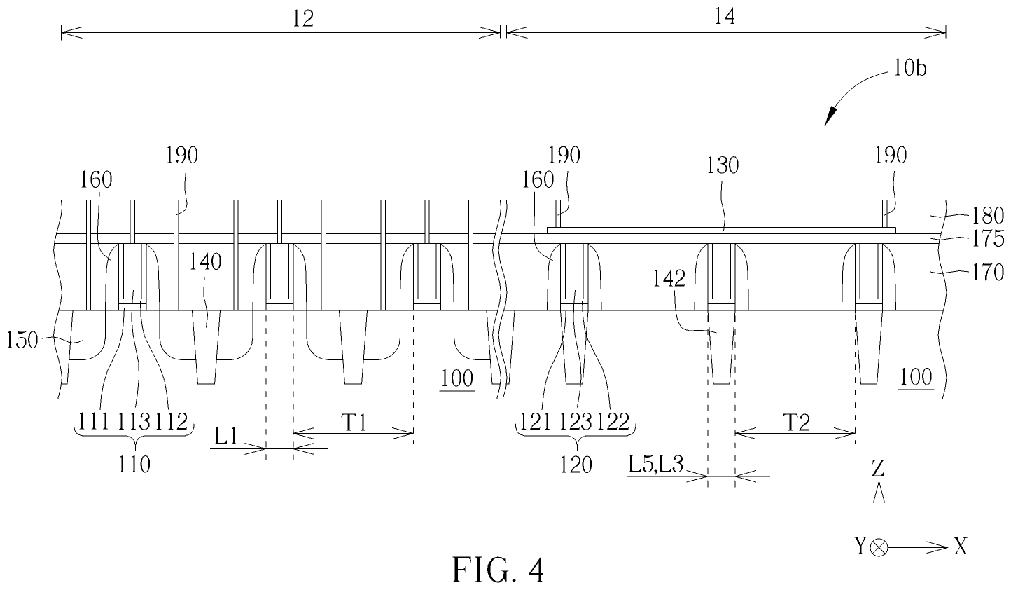

In FIG. 2, in a top view of the semiconductor device 10 (the view angle opposite to the direction Z), the resistor 130 has a first area A1, the plurality of second gates 120 have a total area A2, and the following relationship may be satisfied: 0.14≤A2/A1≤0.7. Thereby, the density of the second gates 120 is moderate. The second gates 120 may provide sufficient support for the resistor 130, and the second gates 120 will not be too dense to be fabricated. In the embodiment, the number of the resistor 130 is one, the first area A1 of the resistor 130 is the projected area of resistor 130 on the XY plane (i.e., the area of the dotted region in FIG. 2). The number of second gates 120 is nine, and the second gates 120 all overlap with the resistor 130 in the top view. Each of the second gates 120 has a projected area on the XY plane (i.e., the area of the hatched region in a second gate 120 in FIG. 2). The total area A2 of the plurality of second gates 120 is equal to the sum of the projected areas of the nine second gates 120 on the XY plane. However, the present disclosure is not limited thereto. The numbers of the resistor 130 and the second gates 120 and the relative positions between the resistor 130 and the second gates 120 may be adjusted according to practical needs. For example, the number of the second gates 120 may be another integer greater than or equal to two, and the number of resistors 130 may also be an integer greater than or equal to two. As shown in FIG. 3, FIG. 3 is a schematic top view of a semiconductor device 10a according to another embodiment of the present disclosure. Similar to FIG. 2, only the first gates 110, the second gates 120 and the resistors 130 are shown in FIG. 3 while other components are omitted. In FIG. 3, the number of the resistors 130 is three, and each of the resistors 130 corresponds to three second gates 120. In the aforementioned relationship, the first area A1 of the resistor 130 may be the projected area of one of the resistors 130 on the XY plane, and the total area A2 of the plurality of second gates 120 may be the sum of the projected areas of three second gates 120 on the XY plane. In FIG. 3, each of the resistors 130 and the second gates 120 corresponding thereto are completely overlapped in the top view, but not limited thereto. In other embodiment, each of the resistors 130 and the second gates 120 corresponding thereto may be partially overlapped in the top view. In this case, in the aforementioned relationship, the first area A1 of the resistor 130 may be the projected area of a single resistor 130 on the XY plane, and the total area A2 of the plurality of second gates 120 may be the sum of the projected areas of the parts of the second gates overlapping with the single resistor 130 on the XY plane. The aforementioned “corresponding” refers that the resistor 130 and the second gates 120 completely overlap or partially overlap with each other in the top view. In addition, when the number of the resistors 130 is greater than or equal to 2, only one of the resistors 130 and the second gates 120 corresponding thereto satisfying the aforementioned relationship is required.

Please refer back to FIG. 2. The number of the first gates 110 may be greater than or equal to two. A first spaced distance T1 is between two of the first gates 110 adjacent to each other in the first direction, a second spaced distance T2 is between two of the second gates 120 adjacent to each other in the first direction, and the first spaced distance T1 may be equal to the second spaced distance T2. Thereby, the yield of the RMG process may be further improved. A third spaced distance T3 is between two of the first gates 110 adjacent to each other in the second direction, a fourth spaced distance T4 is between two of the second gates 120 adjacent to each other in the second direction, and the third spaced distance T3 may be equal to the fourth spaced distance T4. Thereby, the yield of the RMG process may be further improved. When the first spaced distance T1 is equal to the second spaced distance T2, and the third spaced distance T3 is equal to the fourth spaced distance T4, the arrangement of the first gates 110 in the active region 12 is the same as that of the second gates 120 in the resistor region 14, which is beneficial to simplify the design and may avoid the load effect caused by the different densities of components.

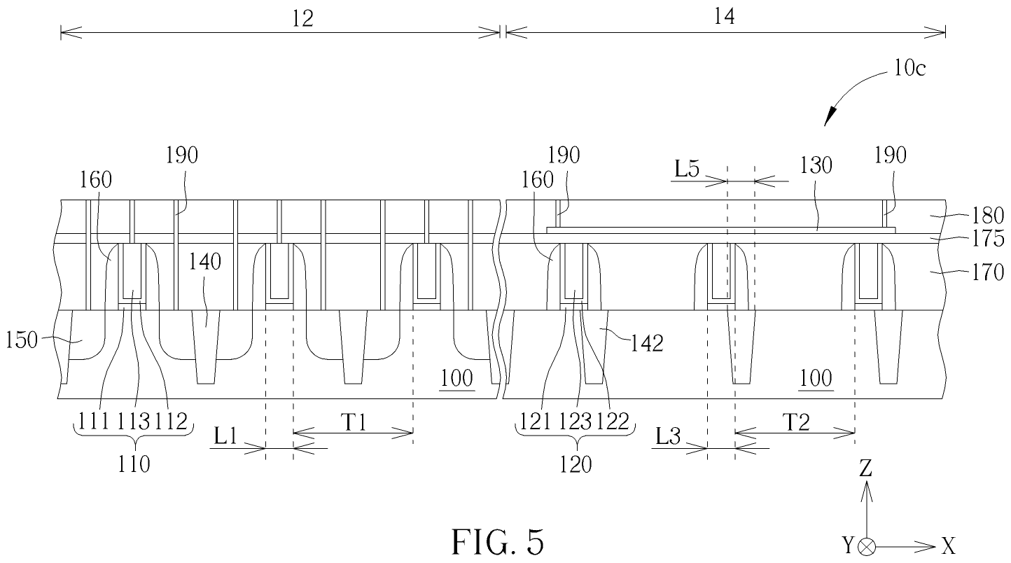

Please refer to FIG. 4, which is a schematic cross-sectional view of a semiconductor device 10b according to further another embodiment of the present disclosure. The main difference between the semiconductor device 10b in FIG. 4 and the semiconductor device 10 in FIG. 1 is the arrangement of the second insulating structures 142. Each of the second insulating structures 142 is disposed in the substrate 100 and is located directly below the second gate 120. That is, the second gate 120 overlaps with the second insulating structure 142 in the top view of the semiconductor device 10b. As shown in FIG. 4, the third length L3 of the second gate 120 is greater than or equal to the fifth length L5 of the second insulating structure 142. In the top view of the semiconductor device 10b, the second gate 120 completely overlaps the second insulating structure 142 in the first direction. Similarly, the second insulating structure 142 has a sixth length (not shown) in the second direction (such as the direction Y), the fourth length L4 of the second gate 120 may be greater than or equal to the sixth length of the second insulating structure 142. In the top view of the semiconductor device 10b, the second gate 120 completely overlaps with the second insulating structure 142 in the second direction. In other words, in the top view of the semiconductor device 10b, the second gate 120 may completely overlap with the second insulating structure 142. Thereby, it is beneficial to improve the supporting effect. In the embodiment, the fifth length L5 in the first direction and the sixth length in the second direction of the second insulating structure 142 gradually change along the height direction (such as the direction Z) of the semiconductor device 10b. Herein, the fifth length L5 and the sixth length are exemplarily decreased from top to bottom along the height direction. The fifth length L5 may be the maximum length of the second insulating structure 142 in the first direction, and the sixth length may be the maximum length of the second insulating structure 142 in the second direction. In the embodiment, the third length L3 is exemplarily equal to the fifth length L5, and the fourth length L4 is exemplarily equal to the sixth length. That is, the bottom area of the second gate 120 may be equal to the top area of the second insulating structure 142.

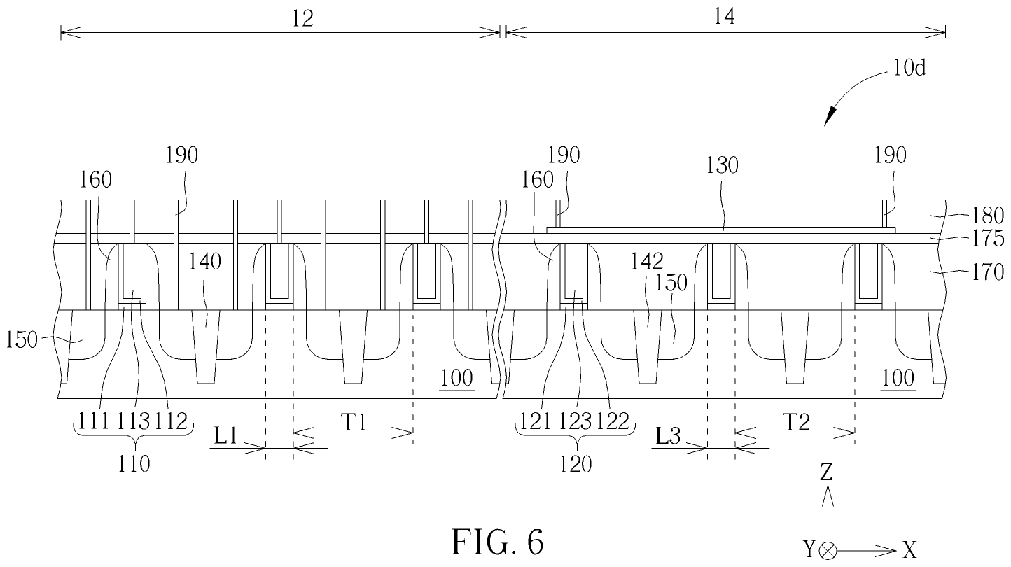

Please refer to FIG. 5, which is a schematic cross-sectional view of a semiconductor device 10c according to yet another embodiment of the present disclosure. The main difference between the semiconductor device 10c in FIG. 5 and the semiconductor device 10b in FIG. 4 is the arrangement of the second insulating structures 142. In the top view of the semiconductor device 10c, the second gate 120 partially overlaps with the second insulating structure 142. As shown in FIG. 5, the third length L3 of the second gate 120 is greater than or equal to the fifth length L5 of the second insulating structure 120. In the top view of the semiconductor device 10c, the second gate 120 partially overlaps with the second insulating structure 142 in the first direction. The second insulating structure 142 has a sixth length (not shown) in the second direction (such as the direction Y), the fourth length L4 of the second gate 120 may be greater than or equal to the sixth length of the second insulating structure 142. In the top view of the semiconductor device 10c, the second gate 120 may completely or partially overlap with the second insulating structure 142 in the second direction. In other words, in the top view of the semiconductor device 10c, the second gate 120 partially overlaps with the second insulating structure 142. Thereby, the adverse effects on the semiconductor device 10c caused by the dishing generated on the second gates 120 and the dishing generated on the second insulating structure 142 in the CMP process may be reduced. For other details of the semiconductor device 10c, reference may be made to the relevant description of the semiconductor device 10b, and are not repeated herein.

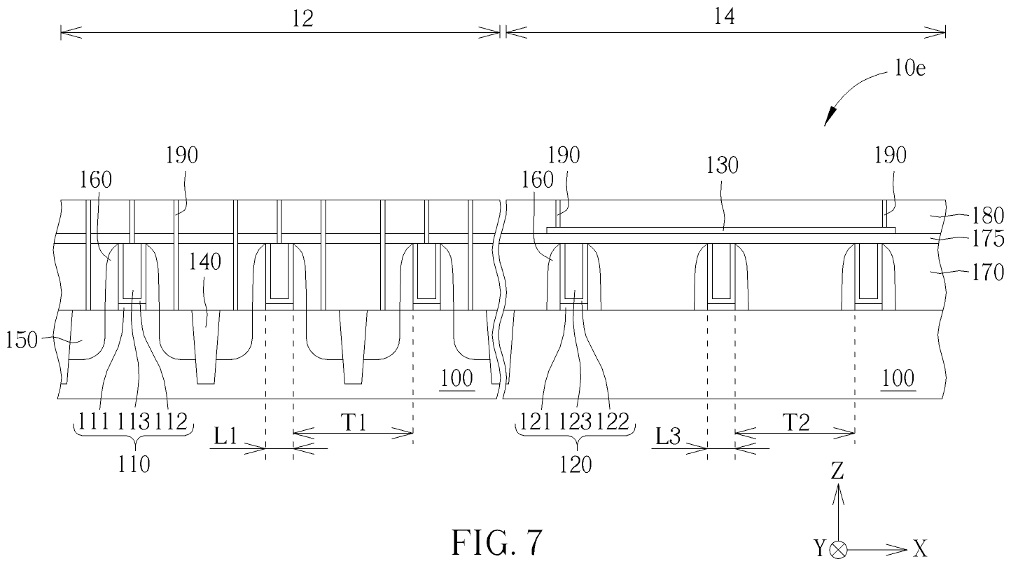

Please refer to FIG. 6, which is a schematic cross-sectional view of a semiconductor device 10d according to yet another embodiment of the present disclosure. The main difference between the semiconductor device 10d in FIG. 6 and the semiconductor device 10 in FIG. 1 is the semiconductor device 10d further includes source/drain regions 150 formed in the substrate 100 and located on both sides of the second gate 120. Thereby, the arrangement of first gates 110, the source/drain regions 150 and the first insulating structures 140 in the active region 12 is the same as that of the second gates 120, the source/drain regions 150 and the second insulating structures 142 in the resistor region 14. That is, the active region 12 and the resistor region 14 of the semiconductor device 10d may not be defined in advance. The region (i.e., the resistor region 14) where the resistor 130 disposed may be determined depending on the product requirements, such as the size and the position of the resistor 130, which is beneficial to improve the design freedom and widen the application of the semiconductor device 10d.

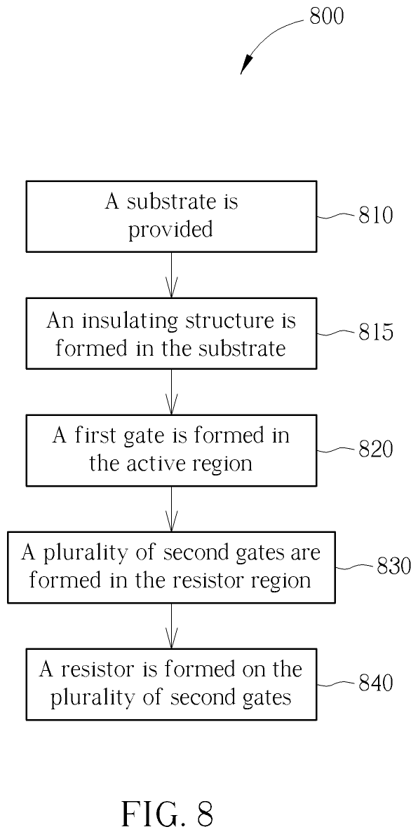

Please refer to FIG. 7, which is a schematic cross-sectional view of a semiconductor device 10e according to yet another embodiment of the present disclosure. The main difference between the semiconductor device 10e in FIG. 7 and the semiconductor device 10 in FIG. 1 is the substrate 100 in the resistor region 14 of the semiconductor device 10e is not disposed with the second insulating structures 142. Thereby, the dishing generated on the second insulating structures 142 caused by the planarization process when fabricating the second insulating structures 142 may be prevented, so that a more uniform support may be provided for the second gates 120 and the resistor 130.

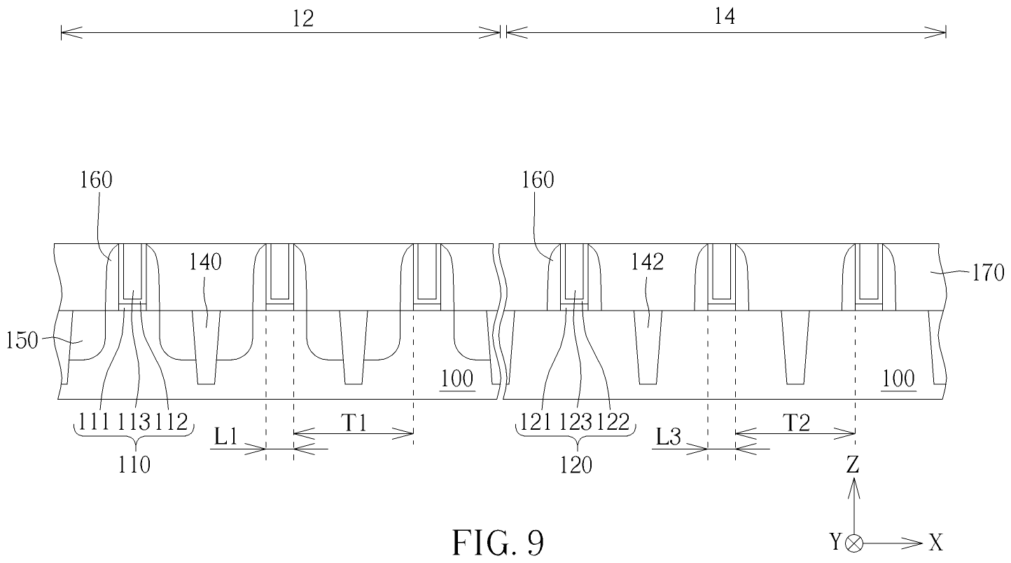

Please refer to FIG. 8, which is a flow diagram showing a method 800 for fabricating a semiconductor device according to another embodiment of the present disclosure. The method includes Step 810 to Step 840. In Step 810, a substrate is provided, wherein the substrate is defined with an active region and a resistor region. In Step 820, a first gate is formed in the active region, wherein the first gate has a first length extending along a first direction and a second length extending along a second direction. In Step 830, a plurality of second gates are formed in the resistor region, wherein each of the second gates has a third length extending along the first direction and a fourth length extending along the second direction, the first length is equal to the third length, and the second length is equal to the fourth length. In Step 840, a resistor is formed on the plurality of second gates.

The method 800 for fabricating the semiconductor device may optionally include Step 815. In Step 815, an insulating structure is formed in the substrate. The insulating structure may be arranged between two of the second gates, or one of the second gates may overlap with the insulating structure in a top view of the semiconductor device according to practical needs. For example, one of the second gates may completely or partially overlap with the insulating structure.

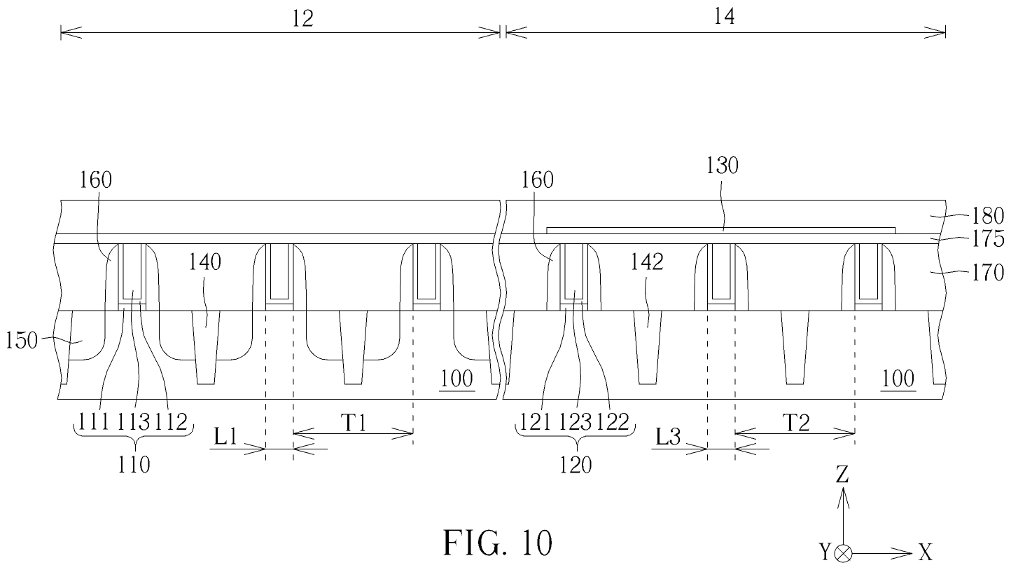

Please refer to FIG. 9 and FIG. 10, which are schematic diagrams showing steps of the method 800 for fabricating the semiconductor device in FIG. 8. FIG. 9 and FIG. 10 exemplarily illustrate how to use the method 800 to fabricate the semiconductor device 10 in FIG. 1. In FIG. 9, the substrate 100 is provided (Step 810), wherein the substrate 100 is defined with the active region 12 and the resistor region 14. The first insulating structures 140 may be formed in the substrate 100 in the active region 12, and the second insulating structures 142 may be formed in the substrate 100 in the resistor region 14 (Step 815). For example, an etching process may be performed with a patterned mask (not shown) to form grooves in the substrate 100 corresponding to the positions of the first insulating structures 140 and the second insulating structures 142. Afterwards, a deposition process is performed to fill the grooves with a dielectric material, and then a portion of the dielectric material may be removed by a planarization process, so that the top surface of the remaining dielectric material is aligned with the top surface of the substrate 100 to complete the fabrication of the first insulating structures 140 and the second insulating structures 142. Next, a gate stack (not shown) is formed on the substrate 100. The gate stack, from bottom to top, may include a gate dielectric material (not shown) and a dummy gate material (not shown) such as polysilicon. The gate stack is patterned to obtain dummy gates (not shown) in the active region 12 and the resistor region 14. Each of the dummy gates may include a gate dielectric layer 112 and a dummy gate material layer (not shown) from bottom to top. Next, light doped drains (LDDs) (not shown) may be formed in the substrate 100 in the active region 12. The spacers 160 may be formed to surround the dummy gates, and the source/drain regions 150 may be formed in the substrate 100 in the active region 12. The LDDs are located on both sides of the dummy gate in the active region 12 and located below the spacer 160. The structure of source/drain regions 150 may be adjusted depending on the first gate 110 being applied to the NMOS or the PMOS. For example, when the first gate 110 is applied to the NMOS, N-type impurities such as arsenic and phosphorus may be implanted in the substrate 100 on both sides of the dummy gate in the active region 12 to form the source/drain regions 150. For another example, when the first gate 110 is applied to the PMOS, grooves (not shown) may be formed in the substrate 100 on both sides of the dummy gate in the active region 12 by isotropic or anisotropic etch, and then a selective epitaxial growth (SEG) may be performed to form an epitaxial layer that can provide stress in the grooves. For example, the epitaxial layer may be a silicon germanium epitaxial layer. Next, an ion implantation process may be performed to implant P-type impurities in the epitaxial layer, such as boron and indium, to form the source/drain regions 150. Next, a first dielectric material is deposited on the substrate 100 to cover the dummy gates, and then a planarization process is performed to remove a portion of the first dielectric material to expose the dummy gate material layers of the dummy gates, so that the top surface of the remaining first dielectric material is aligned with the top surfaces of the dummy gates, and the fabrication of the first dielectric layer 170 is finished. Next, the RMG process is performed to replace the dummy gate material layer of each of the dummy gates in the active region 12 with the high-K dielectric layer 112 and the metal layer 113 and replace the dummy gate material layer of each of the dummy gates in the resistor region 14 with the high-K dielectric layer 122 and the metal layer 123, so as to finish the fabrication of the first gates 110 and the second gates 120 (Step 820 and Step 830), and the semiconductor device shown in FIG. 9 can be obtained. The RMG process is well known in the art and is not repeated herein. As shown in FIG. 10, the second dielectric material is deposited on the first dielectric layer 170, the first gates 110 and the second gates 120. A planarization process is performed to finish the fabrication of the second dielectric layer 175. A resistor material is deposited on the second dielectric layer 175, and then a planarization process and a pattern process are performed to finish the fabrication of the resistor 130 (Step 840). Next, a third dielectric material is deposited on the second dielectric layer 175 and the resistor 130, and then a planarization process is performed to finish the fabrication of the third dielectric layer 180. Thereby, the semiconductor device shown in FIG. 10 can be obtained.

Afterwards, the process of fabricating the contact plugs 190 may be performed. For example, at least one contact hole (not shown) penetrating the first dielectric layer 170 and/or the second dielectric layer 175 and/or the third dielectric layer 180 may be formed. A barrier layer (not shown) and a metal layer (not shown) are sequentially deposited in the contact hole. Afterwards, a planarization process is performed, so that the top surfaces of the barrier layer and the metal layer are aligned with the top surface of the third dielectric layer 185 to form the contact plug 190. Thereby, the semiconductor device 10 shown in FIG. 1 is obtained.

The method for fabricating the semiconductor device 10a in FIG. 3 is similar to the method for fabricating the semiconductor device 10 in FIGS. 1 and 2. The main difference is that the pattern of the mask is changed when patterning the resistor material (Step 840). The methods for fabricating the semiconductor device 10b in FIG. 4, the semiconductor device 10c in FIG. 5, and the semiconductor device 10e in FIG. 7 are similar to the method for fabricating the semiconductor device 10 in FIGS. 1 and 2. The main difference is that the position of the mask is changed when forming the second insulating structures 142, so that the positions of the grooves corresponding to the second insulating structures 142 may be changed, or the resistor region 14 is not formed with the second insulating structures 142. The method for fabricating the semiconductor device 10d in FIG. 6 is similar to the method for fabricating the semiconductor device 10 in FIGS. 1 and 2. The main difference is that the source/drain regions 150 are also formed in the substrate 100 in the resistor region 14 when forming the source/drain regions 150 in the substrate 100 in the active region 12.

In the present disclosure, the second gates 120 disposed in the resistor region 14 are dummy gates.

Compared with the prior art, the present disclosure uses the second gates to support the resistor by disposing the resistor on the second gates, so as to avoid the resistor from dishing due to lack of support during the planarization process such as the chemical mechanical polishing process. With the first length is equal to the third length and the second length is equal to the fourth length, it is beneficial to clearly remove the gate material such as polysilicon in the first gate and the second gates at the same time when performing the metal gate replacement process, and to avoid the heights of the first gates and second gates being different after removing the gate material. Accordingly, the metal bridges between the first gates and/or the second gates can be avoided.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor device, comprising:
a substrate, defined with an active region and a resistor region;
a first gate disposed in the active region, wherein the first gate has a first length extending along a first direction and a second length extending along a second direction;
a plurality of second gates disposed in the resistor region, wherein each of the second gates has a third length extending along the first direction and a fourth length extending along the second direction, the first length is equal to the third length, and the second length is equal to the fourth length; and
a resistor disposed on the plurality of second gates.

2. The semiconductor device of claim 1, wherein in a top view of the semiconductor device, the resistor has a first area A1, the plurality of second gates have a total area A2, and the following relationship is satisfied:
0.14≤A2/A1≤0.7.

3. The semiconductor device of claim 1, wherein the resistor comprises doped polysilicon, metal nitrides, metal oxides, or a combination thereof.

4. The semiconductor device of claim 1, wherein a number of the first gates is greater than or equal to two, a first spaced distance is between two of the first gates adjacent to each other in the first direction, a second spaced distance is between two of the second gates adjacent to each other in the first direction, and the first spaced distance is equal to the second spaced distance.

5. The semiconductor device of claim 4, wherein a third spaced distance is between two of the first gates adjacent to each other in the second direction, a fourth spaced distance is between two of the second gates adjacent to each other in the second direction, and the third spaced distance is equal to the fourth spaced distance.

6. The semiconductor device of claim 1, further comprising:
an insulating structure disposed in the substrate and located between two of the second gates.

7. The semiconductor device of claim 1, further comprising:
an insulating structure disposed in the substrate, wherein in a top view of the semiconductor device, one of the plurality of second gates overlaps with the insulating structure.

8. The semiconductor device of claim 7, wherein the insulating structure has a fifth length in the first direction, and the third length of the second gate is greater than or equal to the fifth length of the insulating structure.

9. The semiconductor device of claim 7, wherein in the top view of the semiconductor device, the one of the plurality of second gates completely overlaps with the insulating structure.

10. The semiconductor device of claim 7, wherein in the top view of the semiconductor device, the one of the plurality of second gates partially overlaps with the insulating structure.

11. A method for fabricating a semiconductor device, comprising:
providing a substrate, wherein the substrate is defined with an active region and a resistor region;
forming a first gate in the active region, wherein the first gate has a first length extending along a first direction and a second length extending along a second direction;
forming a plurality of second gates in the resistor region, wherein each of the second gates has a third length extending along the first direction and a fourth length extending along the second direction, the first length is equal to the third length, and the second length is equal to the fourth length; and
forming a resistor on the plurality of second gates.

12. The method of claim 11, wherein in a top view of the semiconductor device, the resistor has a first area A1, the plurality of second gates have a total area A2, and the following relationship is satisfied:
0.14≤A2/A1≤0.7.

13. The method of claim 11, wherein the resistor comprises doped polysilicon, metal nitrides, metal oxides, or a combination thereof.

14. The method of claim 11, wherein a number of the first gates is greater than or equal to two, a first spaced distance is between two of the first gates adjacent to each other in the first direction, a second spaced distance is between two of the second gates adjacent to each other in the first direction, and the first spaced distance is equal to the second spaced distance.

15. The method of claim 14, wherein a third spaced distance is between two of the first gates adjacent to each other in the second direction, a fourth spaced distance is between two of the second gates adjacent to each other in the second direction, and the third spaced distance is equal to the fourth spaced distance.

16. The method of claim 11, further comprising:
forming an insulating structure in the substrate, wherein the insulating structure is located between two of the second gates.

17. The method of claim 11, further comprising:
forming an insulating structure in the substrate, wherein in a top view of the semiconductor device, one of the plurality of second gates overlaps with the insulating structure.

18. The method of claim 17, wherein the insulating structure has a fifth length in the first direction, and the third length of the second gate is greater than or equal to the fifth length of the insulating structure.

19. The method of claim 17, wherein in the top view of the semiconductor device, the one of the plurality of second gates completely overlaps with the insulating structure.

20. The method of claim 17, wherein in the top view of the semiconductor device, the one of the plurality of second gates partially overlaps with the insulating structure.
